(19) United States
(12) Patent Application Publication
(10) Pub. No.: US 2025/0255102 A1
(43) Pub. Date: Aug. 7, 2025

(54) DISPLAY DEVICE

(71) Applicant: Japan Display Inc., Tokyo (JP)

(72) Inventors: Hideyuki TAKAHASHI, Tokyo (JP); Hiroyuki KIMURA, Tokyo (JP); Hiroshi TABATAKE, Tokyo (JP)

(73) Assignee: Japan Display Inc., Tokyo (JP)

(21) Appl. No.: 18/613,141

(22) Filed: Mar. 22, 2024

(30) Foreign Application Priority Data
Apr. 17, 2023 (JP) 2023-067107

(51) Int. Cl. H10K 59/122; H10K 59/131; H10K 59/35

(52) U.S. Cl. CPC H10K 59/122; H10K 59/131; H10K 59/353

(57) ABSTRACT

According to one embodiment, a display device includes a plurality of subpixels arranged in a first direction and a second direction intersecting with the first direction, and a partition which includes a conductive lower portion and an upper portion protruding from a side surface of the lower portion and surrounds the subpixels. The partition includes first and second partitions arranged across an intervening gap in the first direction and extending in the second direction, and a plurality of protrusions extending from the first partition toward the second partition and spaced apart from the second partition.

### CROSS-REFERENCE TO RELATED APPLICATION

This application is based upon and claims the benefit of priority from Japanese Patent Application No. 2023-067107, filed Apr. 17, 2023, the entire contents of which are incorporated herein by reference.

### FIELD

Embodiments described herein relate generally to a display device.

### BACKGROUND

Recently, display devices to which an organic light emitting diode (OLED) is applied as a display element have been put into practical use. This display element comprises a lower electrode, an organic layer which covers the lower electrode, and an upper electrode which covers the organic layer. Common voltage is applied to the upper electrode of each display element through lines provided in a display area. These upper electrodes and lines constitute a common electrode which overlaps the display area as a whole.

In some cases, an antenna which transmits and receives radio waves for near field communication (NFC) is incorporated into an electronic device comprising a display device in a state where the antenna overlaps the display device. In this case, eddy current could occur in a common electrode because of a magnetic field generated by the antenna. If the resistance of the common electrode is low, the magnetic field generated by eddy current becomes strong and may be a cause of interruption of communication performed by the antenna.

In addition, translucency is required in some display devices. However, if the above lines are formed of a material having light-shielding properties such as metal, the translucency of the display device could be considerably decreased.

### BRIEF DESCRIPTION OF THE DRAWINGS

FIG. 1 is a diagram showing a configuration example of a display device according to a first embodiment.

FIG. 2 is a schematic plan view showing an example of the layout of subpixels.

FIG. 3 is a schematic cross-sectional view of the display device along the III-III line of FIG. 2.

FIG. 4 is a schematic plan view showing some elements of the display device.

FIG. 5 is a schematic plan view in which two segments which are adjacent to each other via a slit are enlarged.

FIG. 6 is a schematic plan view in which the vicinity of a protrusion is enlarged.

FIG. 7 is a schematic cross-sectional view of the display device along the VII-VII line of FIG. 6.

FIG. 8 is a schematic cross-sectional view of the display device along the VIII-VIII line of FIG. 6.

FIG. 9 is a schematic cross-sectional view of the display device along the IX-IX line of FIG. 6.

FIG. 10 is a schematic cross-sectional view showing the process of depositing an upper electrode.

FIG. 11 is a schematic plan view of a configuration which could be applied to the high-resistive portion shown in FIG. 4.

FIG. 12 is a diagram for explaining the effect of the display device according to the first embodiment.

FIG. 13 is a diagram for explaining the effect of the display device according to the first embodiment.

FIG. 14 is a schematic plan view in which segments which are adjacent to each other via a slit are enlarged in a display device according to a second embodiment.

FIG. 15 is a schematic plan view in which segments which are adjacent to each other via a slit are enlarged in a display device according to a third embodiment.

FIG. 16 is a schematic plan view in which segments which are adjacent to each other via a slit are enlarged in a display device according to a fourth embodiment.

FIG. 17 is a schematic plan view showing some elements of a display device according to a fifth embodiment.

FIG. 18 is a schematic plan view showing some elements of a display device according to a sixth embodiment.

FIG. 19 is a schematic plan view in which segments which are adjacent to each other via a slit are enlarged in the display device according to the sixth embodiment.

FIG. 20 is a schematic plan view showing another example which could be applied to the display device according to the sixth embodiment.

FIG. 21 is a schematic plan view showing yet another example which could be applied to the display device according to the sixth embodiment.

FIG. 22 is a schematic plan view showing yet another example which could be applied to the display device according to the sixth embodiment.

FIG. 23 is a schematic plan view showing some elements of a display device according to a seventh embodiment.

FIG. 24 is a schematic plan view showing another example of a configuration which could be applied to the display device according to the seventh embodiment.

### DETAILED DESCRIPTION

In general, according to one embodiment, a display device comprises a plurality of subpixels arranged in a first direction and a second direction intersecting with the first direction, and a partition which includes a conductive lower portion and an upper portion protruding from a side surface of the lower portion and surrounds the subpixels. The partition includes first and second partitions arranged across an intervening gap in the first direction and extending in the second direction, and a plurality of protrusions extending from the first partition toward the second partition and spaced apart from the second partition.

According to another embodiment, a display device comprises a plurality of subpixels arranged in a first direction and a second direction intersecting with the first direction, and a partition which includes a conductive lower portion and an upper portion protruding from a side surface of the lower portion and surrounds the subpixels. The partition includes first and second partitions arranged across an intervening gap in the first direction and extending in the second direction. The subpixels include a plurality of first subpixels arranged in the second direction between the first partition and the second partition. The partition is not provided between the adjacent first subpixels.

Each embodiment can provide a display device comprising an improved interconnection structure.

Embodiments will be described with reference to the accompanying drawings.

The disclosure is merely an example, and proper changes in keeping with the spirit of the invention, which are easily conceivable by a person of ordinary skill in the art, come within the scope of the invention as a matter of course. In addition, in some cases, in order to make the description clearer, the widths, thicknesses, shapes, etc., of the respective parts are illustrated schematically in the drawings, rather than as an accurate representation of what is implemented. However, such schematic illustration is merely exemplary, and in no way restricts the interpretation of the invention. In addition, in the specification and drawings, structural elements which function in the same or a similar manner to those described in connection with preceding drawings are denoted by like reference numbers, detailed description thereof being omitted unless necessary.

In the drawings, in order to facilitate understanding, an X-axis, a Y-axis and a Z-axis orthogonal to each other are shown depending on the need. A direction parallel to the X-axis is referred to as an X-direction. A direction parallel to the Y-axis is referred to as a Y-direction. A direction parallel to the Z-axis is referred to as a Z-direction. The Z-direction is a normal direction relative to a plane including the X-direction and the Y-direction. When various elements are viewed parallel to the Z-direction, the appearance is defined as a plan view.

The display device of each embodiment is an organic electroluminescent display device comprising an organic light emitting diode (OLED) as a display element, and could be mounted on various types of electronic devices such as a television, a personal computer, a vehicle-mounted device, a tablet, a smartphone, a mobile phone and a wearable terminal.

### First Embodiment

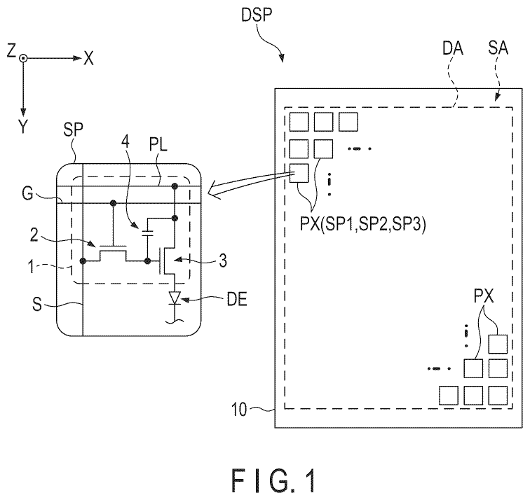

FIG. 1 is a diagram showing a configuration example of a display device DSP according to a first embodiment. The display device DSP comprises an insulating substrate 10. The substrate 10 has a display area DA which displays an image, and a surrounding area SA around the display area DA. The substrate 10 may be glass or a resinous film having flexibility.

In the embodiment, the substrate 10 is rectangular as seen in plan view. It should be noted that the shape of the substrate 10 in plan view is not limited to a rectangle and may be another shape such as a square, a circle or an oval.

The display area DA comprises a plurality of pixels PX arrayed in matrix in an X-direction and a Y-direction. Each pixel includes a plurality of subpixels SP which display different colors. This embodiment assumes a case where each pixel PX includes a blue subpixel SP1, a green subpixel SP2 and a red subpixel SP3. However, each pixel PX may include a subpixel SP which exhibits another color such as white in addition to subpixels SP1, SP2 and SP3 or instead of one of subpixels SP1, SP2 and SP3.

Each subpixel SP comprises a pixel circuit 1 and a display element DE driven by the pixel circuit 1. The pixel circuit 1 comprises a pixel switch 2, a drive transistor 3 and a capacitor 4. The pixel switch 2 and the drive transistor 3 are, for example, switching elements consisting of a thin-film transistor.

A plurality of scanning lines G which supply a scanning signal to the pixel circuits 1 of the subpixels SP, a plurality of signal lines S which supply a video signal to the pixel circuits 1 of the subpixels SP and a plurality of power lines PL are provided in the display area DA. In the example of FIG. 1, the scanning lines G and the power lines PL extend in the X-direction, and the signal lines S extend in the Y-direction.

The gate electrode of the pixel switch 2 is connected to the scanning line G. One of the source electrode and drain electrode of the pixel switch 2 is connected to the signal line S. The other one is connected to the gate electrode of the drive transistor 3 and the capacitor 4. In the drive transistor 3, one of the source electrode and the drain electrode is connected to the power line PL and the capacitor 4, and the other one is connected to the display element DE.

It should be noted that the configuration of the pixel circuit 1 is not limited to the example shown in the figure. For example, the pixel circuit 1 may comprise more thin-film transistors and capacitors.

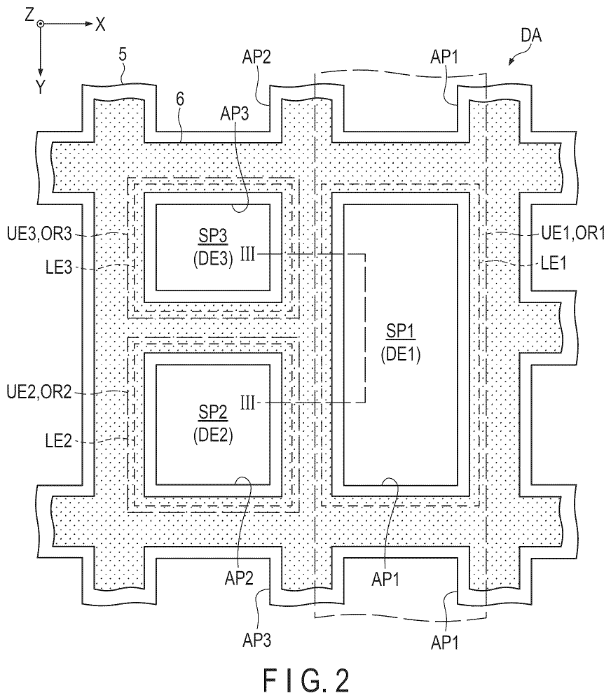

FIG. 2 is a schematic plan view showing an example of the layout of subpixels SP1, SP2 and SP3. In the example of FIG. 2, each of subpixels SP2 and SP3 is adjacent to subpixel SP1 in the X-direction. Further, subpixels SP2 and SP3 are arranged in the Y-direction.

When subpixels SP1, SP2 and SP3 are provided in line with this layout, a column in which subpixels SP2 and SP3 are alternately provided in the Y-direction and a column in which a plurality of subpixels SP1 are repeatedly provided in the Y-direction are formed in the display area DA. These columns are alternately arranged in the X-direction. It should be noted that the layout of subpixels SP1, SP2 and SP3 is not limited to the example of FIG. 2.

A rib 5 is provided in the display area DA. The rib 5 has pixel apertures AP1, AP2 and AP3 in subpixels SP1, SP2 and SP3, respectively. In the example of FIG. 2, the pixel aperture AP1 is larger than the pixel aperture AP2. The pixel aperture AP2 is larger than the pixel aperture AP3. Thus, among subpixels SP1, SP2 and SP3, the aperture ratio of subpixel SP1 is the greatest, and the aperture ratio of subpixel SP3 is the least.

Subpixel SP1 comprises a lower electrode LE1, an upper electrode UE1 and an organic layer OR1 overlapping the pixel aperture AP1. Subpixel SP2 comprises a lower electrode LE2, an upper electrode UE2 and an organic layer OR2 overlapping the pixel aperture AP2. Subpixel SP3 comprises a lower electrode LE3, an upper electrode UE3 and an organic layer OR3 overlapping the pixel aperture AP3.

Of the lower electrode LE1, the upper electrode UE1 and the organic layer OR1, the portions which overlap the pixel aperture AP1 constitute the display element DE1 of subpixel SP1. Of the lower electrode LE2, the upper electrode UE2 and the organic layer OR2, the portions which overlap the pixel aperture AP2 constitute the display element DE2 of subpixel SP2. Of the lower electrode LE3, the upper electrode UE3 and the organic layer OR3, the portions which overlap the pixel aperture AP3 constitute the display element DE3 of subpixel SP3. Each of the display elements DE1, DE2 and DE3 may further include a cap layer as described later. The rib 5 surrounds each of these display elements DE1, DE2 and DE3.

A conductive partition 6 is provided on the rib 5. The partition 6 overlaps the rib 5 as a whole and has the same planar shape as the rib 5. In other words, the partition 6 has an aperture in each of subpixels SP1, SP2 and SP3. From another viewpoint, each of the rib 5 and the partition 6 has a grating shape as seen in plan view and surrounds each of subpixels SP1, SP2 and SP3.

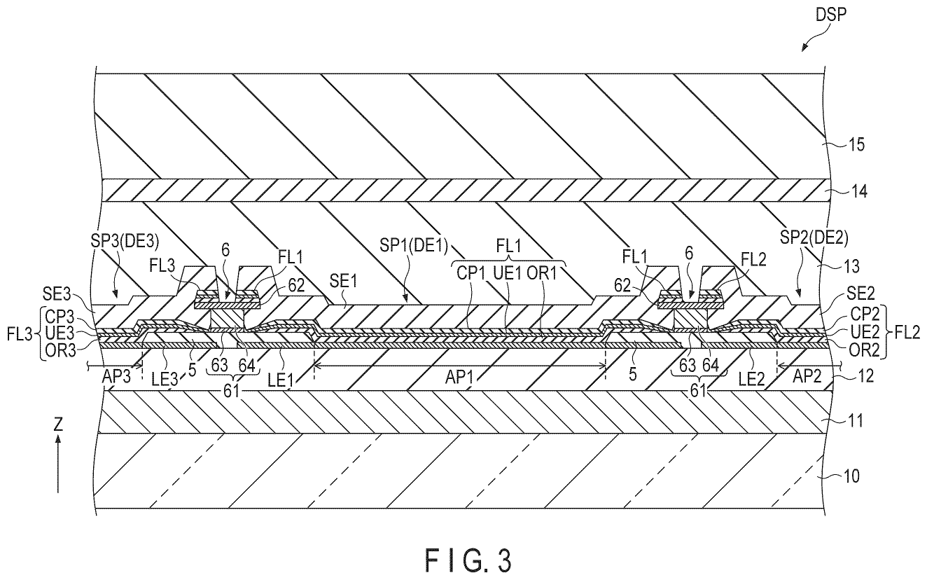

FIG. 3 is a schematic cross-sectional view of the display device DSP along the III-III line of FIG. 2. A circuit layer 11 is provided on the substrate 10 described above. The circuit layer 11 includes various circuits and lines such as the pixel circuits 1, scanning lines G, signal lines S and power lines PL shown in FIG. 1. The circuit layer 11 is covered with an organic insulating layer 12. The organic insulating layer 12 functions as a planarization film which planarizes the irregularities formed by the circuit layer 11.

The lower electrodes LE1, LE2 and LE3 are provided on the organic insulating layer 12. The rib 5 is provided on the organic insulating layer 12 and the lower electrodes LE1, LE2 and LE3. The end portions of the lower electrodes LE1, LE2 and LE3 are covered with the rib 5. Although not shown in the section of FIG. 3, the lower electrodes LE1, LE2 and LE3 are connected to the respective pixel circuits 1 of the circuit layer 11 through respective contact holes provided in the organic insulating layer 12.

The partition 6 includes a conductive lower portion 61 provided on the rib 5 and an upper portion 62 provided on the lower portion 61. The upper portion 62 has a width greater than that of the lower portion 61. By this configuration, the both end portions of the upper portion 62 protrude relative to the side surfaces of the lower portion 61. This shape of the partition 6 is called an overhang shape.

In the example of FIG. 3, the lower portion 61 has a bottom portion 63 provided on the rib 5, and a stem portion 64 provided on the bottom portion 63. For example, the bottom portion 63 is formed so as to be thinner than the stem portion 64. However, the configuration is not limited to this example. In the example of FIG. 3, the side surfaces of the bottom portion 63 and the stem portion 64 are aligned with each other. However, the both end portions of the bottom portion 63 may protrude from the side surfaces of the stem portion 64.

The organic layer OR1 covers the lower electrode LE1 through the pixel aperture AP1. The upper electrode UE1 covers the organic layer OR1 and faces the lower electrode LE1. The organic layer OR2 covers the lower electrode LE2 through the pixel aperture AP2. The upper electrode UE2 covers the organic layer OR2 and faces the lower electrode LE2. The organic layer OR3 covers the lower electrode LE3 through the pixel aperture AP3. The upper electrode UE3 covers the organic layer OR3 and faces the lower electrode LE3. The upper electrodes UE1, UE2 and UE3 are in contact with the side surfaces of the lower portions 61 of the partition 6.

The display element DE1 includes a cap layer CP1 provided on the upper electrode UE1. The display element DE2 includes a cap layer CP2 provided on the upper electrode UE2. The display element DE3 includes a cap layer CP3 provided on the upper electrode UE3. The cap layers CP1, CP2 and CP3 function as optical adjustment layers which improve the extraction efficiency of the light emitted from the organic layers OR1, OR2 and OR3, respectively.

In the following explanation, a multilayer body including the organic layer OR1, the upper electrode UE1 and the cap layer CP1 is called a stacked film FL1. A multilayer body including the organic layer OR2, the upper electrode UE2 and the cap layer CP2 is called a stacked film FL2. A multilayer body including the organic layer OR3, the upper electrode UE3 and the cap layer CP3 is called a stacked film FL3.

The stacked film FL1 is partly located on the upper portion 62. This portion is spaced apart from, of the stacked film FL1, the portion located under the partition 6 (in other words, the portion which constitutes the display element DE1). Similarly, the stacked film FL2 is partly located on the upper portion 62. This portion is spaced apart from, of the stacked film FL2, the portion located under the partition 6 (in other words, the portion which constitutes the display element DE2). Further, the stacked film FL3 is partly located on the upper portion 62. This portion is spaced apart from, of the stacked film FL3, the portion located under the partition 6 (in other words, the portion which constitutes the display element DE3).

Sealing layers SE1, SE2 and SE3 are provided in subpixels SP1, SP2 and SP3, respectively. The sealing layer SE1 continuously covers the stacked film FL1 and the partition 6 around subpixel SP1. The sealing layer SE2 continuously covers the stacked film FL2 and the partition 6 around subpixel SP2. The sealing layer SE3 continuously covers the stacked film FL3 and the partition 6 around subpixel SP3.

In the example of FIG. 3, the stacked film FL1 and sealing layer SE1 located on the partition 6 between subpixels SP1 and SP2 are spaced apart from the stacked film FL2 and sealing layer SE2 located on this partition 6. The stacked film FL1 and sealing layer SE1 located on the partition 6 between subpixels SP1 and SP3 are spaced apart from the stacked film FL3 and sealing layer SE3 located on this partition 6.

The sealing layers SE1, SE2 and SE3 are covered with a resin layer 13. The resin layer 13 is covered with a sealing layer 14. The sealing layer 14 is covered with a resin layer 15. The resin layers 13 and 15 and the sealing layer 14 are continuously provided in at least the entire display area DA and partly extend in the surrounding area SA as well.

A cover member such as a polarizer, a touch panel, a protective film or a cover glass may be further provided above the resin layer 15. This cover member may be attached to the resin layer 15 via, for example, an adhesive layer such as an optical clear adhesive (OCA).

The organic insulating layer 12 is formed of an organic insulating material such as polyimide. Each of the rib 5 and the sealing layers 14, SE1, SE2 and SE3 is formed of an inorganic insulating material such as silicon nitride (SiNx), silicon oxide (SiOx), silicon oxynitride (SiON) or aluminum oxide (Al₂O₃). For example, the rib 5 is formed of silicon oxynitride, and each of the sealing layers 14, SE1, SE2 and SE3 is formed of silicon nitride. Each of the resin layers 13 and 15 is formed of, for example, a resinous material (organic insulating material) such as epoxy resin or acrylic resin.

Each of the lower electrodes LE1, LE2 and LE3 has a reflective layer formed of, for example, silver (Ag), and a pair of conductive oxide layers covering the upper and lower surfaces of the reflective layer. Each conductive oxide layer may be formed of, for example, a transparent conductive oxide such as indium tin oxide (ITO), indium zinc oxide (IZO) or indium gallium zinc oxide (IGZO).

Each of the upper electrodes UE1, UE2 and UE3 is formed of, for example, a metal material such as an alloy of magnesium and silver (MgAg). For example, the lower electrodes LE1, LE2 and LE3 correspond to anodes, and the upper electrodes UE1, UE2 and UE3 correspond to cathodes.

For example, each of the organic layers OR1, OR2 and OR3 comprises a multilayer structure consisting of a hole injection layer, a hole transport layer, an electron blocking layer, a light emitting layer, a hole blocking layer, an electron transport layer and an electron injection layer. Each of the organic layers OR1, OR2 and OR3 may comprise a tandem structure including a plurality of light emitting layers.

Each of the cap layers CP1, CP2 and CP3 comprises, for example, a multilayer structure in which a plurality of transparent thin films are stacked. The thin films may include a thin film formed of an inorganic material and a thin film formed of an organic material. These thin films have refractive indices different from each other. For example, the refractive indices of these thin films are different from the refractive indices of the upper electrodes UE1, UE2 and UE3 and the refractive indices of the sealing layers SE1, SE2 and SE3. It should be noted that at least one of the cap layers CP1, CP2 and CP3 may be omitted.

Each of the bottom portion 63 and stem portion 64 of the partition 6 is formed of a metal material. For the metal material of the bottom portion 63, for example, molybdenum (Mo), titanium nitride (TiN), a molybdenum-tungsten alloy (MoW) or a molybdenum-niobium alloy (MoNb) can be used. For the metal material of the stem portion 64, for example, aluminum, an aluminum-neodymium alloy (AlNd), an aluminum-yttrium alloy (AlY) or an aluminum-silicon alloy (AlSi) can be used. It should be noted that the stem portion 64 may be formed of an insulating material.

For example, the upper portion 62 of the partition 6 comprises a multilayer structure consisting of a lower layer formed of a metal material and an upper layer formed of conductive oxide. For the metal material forming the lower layer, for example, titanium, titanium nitride, molybdenum, tungsten, a molybdenum-tungsten alloy or a molybdenum-niobium alloy can be used. For the conductive oxide forming the upper layer, for example, ITO or IZO can be used. It should be noted that the upper portion 62 may comprise a single-layer structure of a metal material. The upper portion 62 may further include a layer formed of an insulating material.

Common voltage is applied to the partition 6. This common voltage is applied to each of the upper electrodes UE1, UE2 and UE3 which are in contact with the side surfaces of the lower portions 61. Pixel voltage is applied to the lower electrodes LE1, LE2 and LE3 through the pixel circuits 1 of subpixels SP1, SP2 and SP3, respectively, based on the video signals of the signal lines S.

The organic layers OR1, OR2 and OR3 emit light based on the application of voltage. Specifically, when a potential difference is formed between the lower electrode LE1 and the upper electrode UE1, the light emitting layer of the organic layer OR1 emits light in a blue wavelength range. When a potential difference is formed between the lower electrode LE2 and the upper electrode UE2, the light emitting layer of the organic layer OR2 emits light in a green wavelength range. When a potential difference is formed between the lower electrode LE3 and the upper electrode UE3, the light emitting layer of the organic layer OR3 emits light in a red wavelength range.

As another example, the light emitting layers of the organic layers OR1, OR2 and OR3 may emit light exhibiting the same color (for example, white). In this case, the display device DSP may comprise color filters which convert the light emitted from the light emitting layers into light exhibiting colors corresponding to subpixels SP1, SP2 and SP3. The display device DSP may comprise a layer including quantum dots which generate light exhibiting colors corresponding to subpixels SP1, SP2 and SP3 by the excitation caused by the light emitted from the light emitting layers.

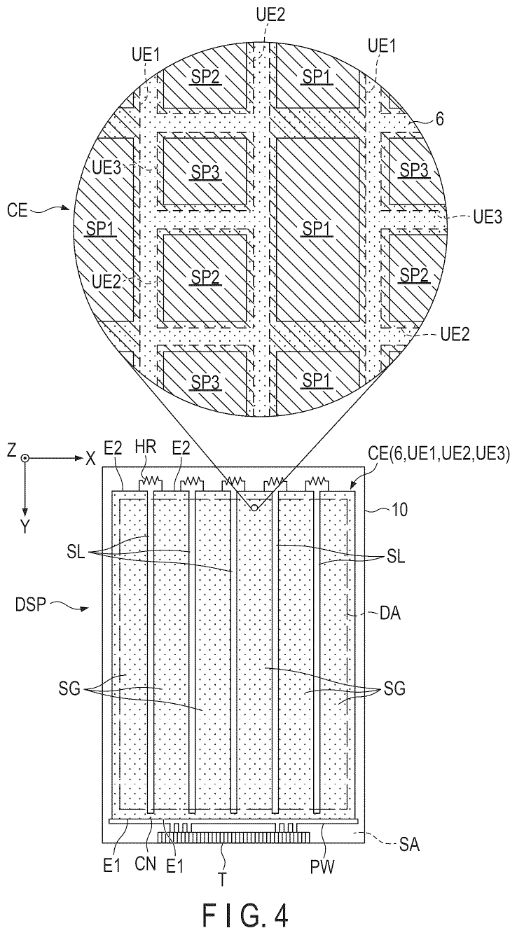

FIG. 4 is a schematic plan view showing some elements of the display device DSP. The partition 6 and the upper electrodes UE1, UE2 and UE3 constitute a common electrode CE which applies common voltage to the display elements DE1, DE2 and DE3. As shown in the enlarged view of FIG. 4, the upper electrodes UE1, UE2 and UE3 are provided in subpixels SP1, SP2 and SP3 included in the display area DA, and further, the partition 6 is provided in the gaps of the upper electrodes UE1, UE2 and UE3. Thus, the common electrode CE overlaps the display area DA as a whole.

A terminal portion T including a plurality of pads is provided in the surrounding area SA. A flexible printed circuit (FPC) is connected to the terminal portion T via, for example, a conductive adhesive material. Voltage and signals necessary for image display are supplied through these flexible printed circuit and terminal portion T.

Further, a power supply line PW is provided in the surrounding area SA. Common voltage is applied to the power supply line PW from the terminal portion T. In the example of FIG. 4, the power supply line PW extends in the X-direction between the terminal portion T and the display area DA.

The common electrode CE has a plurality of slits SL. In the example of FIG. 4, the common electrode CE has five slits SL. However, the number of slits SL is not limited to this example. The common electrode CE is divided into a plurality of segments SG by these slits SL.

In this embodiment, each slit SL extends in the Y-direction. From another viewpoint, each slit SL extends parallel to the signal lines S shown in FIG. 1. The intervals of the slits SL in the X-direction are, for example, constant. In this case, the widths of the segments SG in the X-direction are equal to each other.

Each segment SG has a first end portion E1 and a second end portion E2 in the Y-direction (the extension direction of the slits SL). The first end portion E1 of each segment SG is located on the terminal portion T side and connected to the power supply line PW.

In the example of FIG. 4, the common electrode CE has a plurality of connection portions CN which connect the first end portions E1 of the adjacent segments SG to each other. The connection portions CN are formed by the partition 6. To the contrary, the second end portions E2 of the adjacent segments SG are spaced apart from each other via the slits SL. In other words, the end portions of the slits SL on the second end portion E2 side reach the outer edge (the outline in plan view) of the common electrode CE.

In the example of FIG. 4, the second end portions E2 of the adjacent segments SG are connected to each other by high-resistive portions HR. Each high-resistive portion HR has a resistance which is higher than that of each segment SG. The high-resistive portions HR are provided in the surrounding area SA.

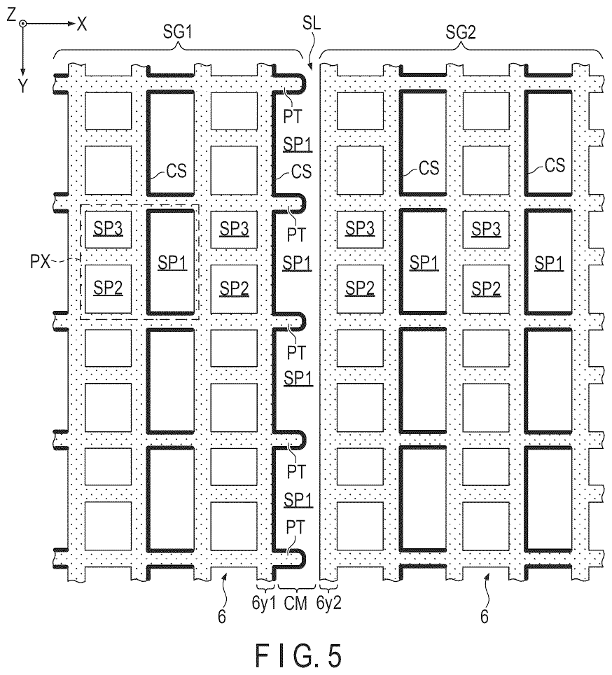

FIG. 5 is a schematic plan view in which two segments SG which are adjacent to each other via a slit SL are enlarged. In the following explanation, the segment SG located on the left side of the slit SL in FIG. 5 is called a first segment SG1, and the segment SG located on the right side is called a second segment SG2. The partition 6 of the first segment SG1 and the partition 6 of the second segment SG are divided from each other by the slit SL.

As described above, a column in which subpixels SP2 and SP3 are alternately provided in the Y-direction and a column in which a plurality of subpixels SP1 are repeatedly provided in the Y-direction are formed in the display area DA. The slit SL is provided along a column in which a plurality of subpixels SP1 are repeatedly provided in the Y-direction. In the following explanation, the column of subpixels SP1 along the slit SL is called a subpixel column CM.

The whole circumferences of subpixels SP1 excluding the subpixel column CM and subpixels SP2 and SP3 are surrounded by the partition 6. However, subpixels SP1 of the subpixel column CM are not completely surrounded by the partition 6.

The first segment SG1 has a first partition 6y1 which is adjacent to the slit SL. The second segment SG2 has a second partition 6y2 which is adjacent to the slit SL. Both of these partitions 6y1 and 6y2 extend in the Y-direction. The partitions 6y1 and 6y2 are arranged in the X-direction across the intervening subpixel column CM.

The first segment SG1 has a plurality of protrusions PT. The protrusions PT extend from the first partition 6y1 toward the second partition 6y2 and are spaced apart from the second partition 6y2. In the embodiment, the protrusions PT are provided for the respective boundaries of subpixels SP1 constituting the subpixel column CM. From another viewpoint, one subpixel SP1 is provided between two protrusions PT which are adjacent to each other in the Y-direction.

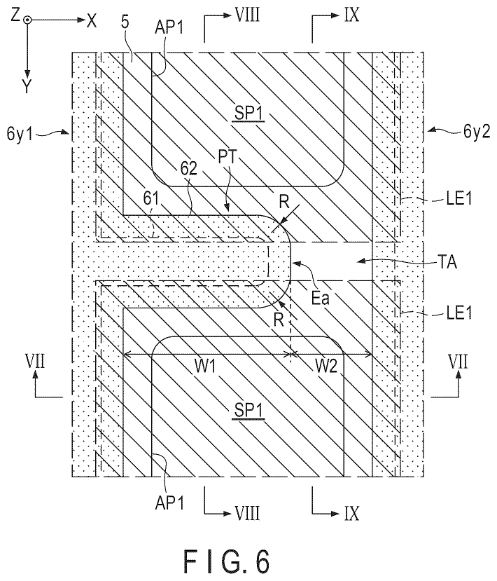

FIG. 6 is a schematic plan view in which the vicinity of a protrusion PT is enlarged. This figure also shows schematic planar shapes of the rib 5 and the lower electrodes LE1. The portions shown by a dotted pattern correspond to the partition 6. The portions shown by a diagonal pattern correspond to the lower electrodes LE1.

The protrusion PT has the lower portion 61 and the upper portion 62 in a manner similar to that of the other portion of the partition 6. The protrusion PT is provided on the rib 5 between adjacent subpixels SP1.

A transmissive area TA is formed near the protrusion PT. The transmissive area TA is surrounded by two lower electrodes LE1 which are arranged in the Y-direction, the distal end portion Ea of the protrusion PT and the second partition 6y2.

The protrusion PT has width W1 in the X-direction. Width W1 corresponds to the distance from the end portion of the upper portion 62 in the proximal portion of the protrusion PT to the end portion of the upper portion 62 in the distal end portion Ea of the protrusion PT in the X-direction. The transmissive area TA has width W2 in the X-direction. Width W2 corresponds to the distance between the end portion of the upper portion 62 in the distal end portion Ea and the end portion of the upper portion 62 of the partition 6 facing the protrusion PT in the X-direction. In the example of FIG. 6, width W1 is greater than width W2. However, the configuration is not limited to this example. Width W1 may be less than or equal to width W2.

The distal end portion Ea of the protrusion PT has a rounded planar shape. Specifically, the upper portion 62 has an arcuate shape with radius R of curvature in the corner portions located at the both ends of the distal end portion Ea. The lower portion 61 also has an arcuate shape along the upper portion 62. Radius R of curvature is, for example, 2 to 4 μm. The distal end portion Ea may be rounded like a semicircle as a whole.

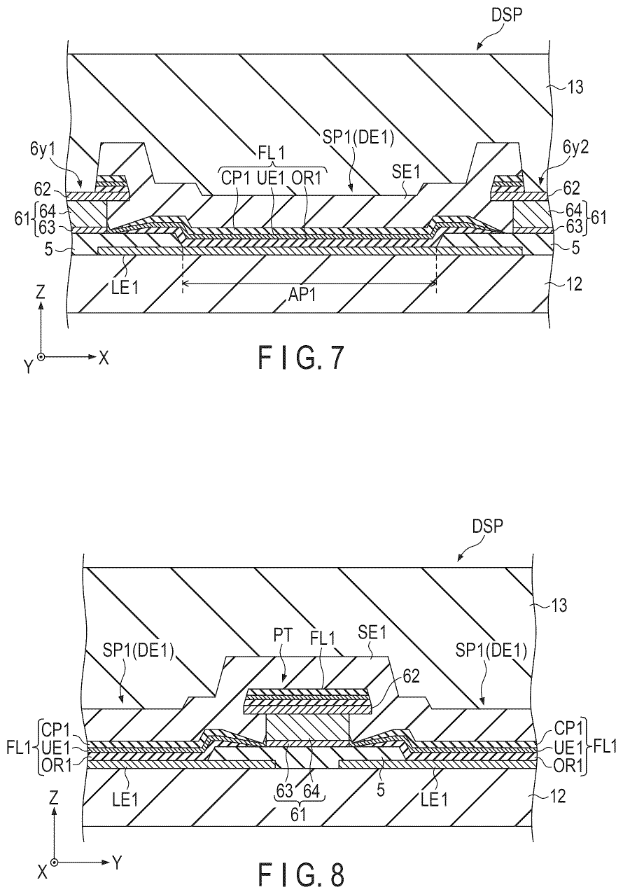

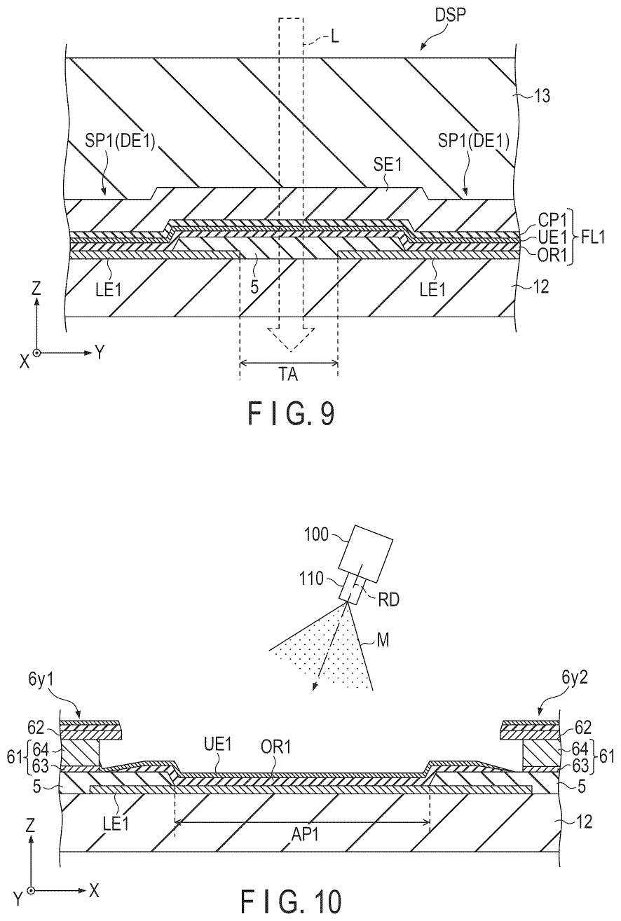

FIG. 7 is a schematic cross-sectional view of the display device DSP along the VII-VII line of FIG. 6. FIG. 8 is a schematic cross-sectional view of the display device DSP along the VIII-VIII line of FIG. 6. FIG. 9 is a schematic cross-sectional view of the display device DSP along the IX-IX line of FIG. 6. In these figures, the illustrations of the substrate 10, the circuit layer 11, the sealing layer 14 and the resin layer 15 are omitted.

The configuration of subpixel SP1 (display element DE1) shown in FIG. 7 is substantially the same as that shown in FIG. 3. It should be noted that, in the section of FIG. 7, although the upper electrode UE1 is in contact with the side surface of the lower portion 61 of the first partition 6y1, the upper electrode UE1 is not in contact with the side surface of the lower portion 61 of the second partition 6y2. This configuration prevents the upper electrode UE1 from electrically connecting the partitions 6y1 and 6y2 to each other. Thus, the effectiveness of the slit SL is ensured.

In the example of FIG. 8, each of the upper electrodes UE1 of subpixels SP1 (display elements DE1) which are adjacent to each other via the protrusion PT is in contact with a corresponding side surface of the lower portion 61 of the protrusion PT. However, at least one of these upper electrodes UE1 may not be in contact with the side surface of the lower portion 61.

The upper portion 62 of the protrusion PT is entirely covered with the stacked film FL1 (the organic layer OR1, the upper electrode UE1 and the cap layer CP1). Further, the sealing layer SE1 continuously covers the stacked film FL1 of each of subpixels SP1 which are adjacent to each other via the protrusion PT, and the stacked film FL1 located on the upper portion 62.

As shown in FIG. 9, the stacked film FL1 extends on the rib 5 without being divided in the transmissive area TA. Neither the lower electrode LE1 nor the partition 6 is provided in the transmissive area TA. Thus, external light L which enters the transmissive area TA can be transmitted to the lower side of the display device DSP without being blocked by the lower electrode LE1 or the partition 6.

FIG. 10 is a schematic cross-sectional view showing the process of depositing the upper electrode UE1. This figure shows a section including the partitions 6y1 and 6y2 in a manner similar to that of FIG. 7. The upper electrode UE1 is formed by vapor deposition. Specifically, the substrate in which the organic layer OR1 is formed is conveyed to a chamber for forming the upper electrode UE1. An evaporation source 100 is provided in this chamber. An evaporation material M is emitted from the nozzle 110 of the evaporation source 100.

The evaporation material M is emitted from the nozzle 110 while spreading. The upper electrode UE1 formed of the evaporation material M attached to the substrate is divided by the partitions 6y1 and 6y2 having an overhang shape.

In the section of FIG. 10, the emission direction RD of the evaporation material M inclines with respect to a Z-direction such that the evaporation material M heads toward the partition 6y1. Thus, the evaporation material M is satisfactorily attached to the side surface of the lower portion 61 of the first partition 6y1. To the contrary, the evaporation material M heading toward the side surface of the lower portion 61 of the second partition 6y2 is blocked by the upper portion 62 of the second partition 6y2. Thus, the attachment of the evaporation material M to the lower portion 61 of the second partition 6y2 is prevented.

By inclining the emission direction RD of the evaporation material M in this manner, as shown in FIG. 7 to FIG. 9, it is possible to form the upper electrode UE1 which is in contact with the side surfaces of the lower portions 61 of the first partition 6y1 and the protrusion PT and is not in contact with the side surface of the lower portion 61 of the second partition 6y2. It should be noted that, in FIG. 5, portions corresponding to contact sides CS in which the upper electrodes UE1 are in contact with the side surfaces of the lower portions 61 in the outline of the partition 6 are shown by thick lines.

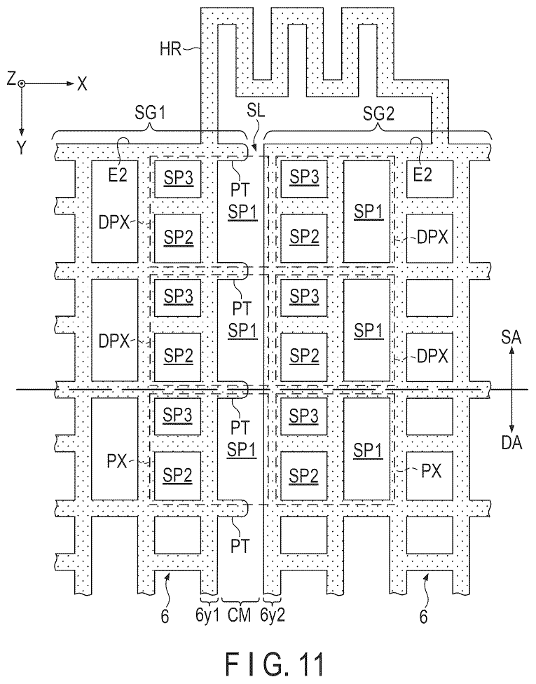

FIG. 11 is a schematic plan view of a configuration which could be applied to the high-resistive portion HR shown in FIG. 4. This figure shows the vicinity of the second end portions E2 of the segments SG1 and SG2 shown in FIG. 5.

Dummy pixels DPX are provided in the surrounding area SA. Each dummy pixel DPX includes subpixels SP1, SP2 and SP3 in a manner similar to that of pixels PX. However, subpixels SP1, SP2 and SP3 of dummy pixels DPX are configured such that they do not emit light. For example, the pixel aperture AP1, AP2 or AP3 is not provided in the rib 5 regarding subpixels SP1, SP2 and SP3 of each dummy pixel DPX. Therefore, even if a potential difference is formed between the lower electrode LE1, LE2 or LE3 and the upper electrode UE1, UE2 or UE3, the organic layer OR1, OR2 or OR3 between them does not emit light.

In the example of FIG. 11, two dummy pixels DPX are arranged in the Y-direction in the surrounding area SA. However, the layout form of dummy pixels DPX is not limited to this example. It should be noted that a similar dummy pixel DPX is provided in a side of the display area DA.

The high-resistive portion HR is formed by the partition 6. Thus, the high-resistive portion HR includes the lower portion 61 and the upper portion 62 which protrudes from the side surfaces of the lower portion 61. The high-resistive portion HR has a shape which meanders a plurality of times and connects the second end portions E2 of the segments SG1 and SG2 to each other. In this meandering shape, the path which connects the segments SG1 and SG2 to each other via the high-resistive portion HR is elongated. Thus, the resistance of the circuit including this path can be increased.

Here, examples of the effects obtained from the embodiment are explained.

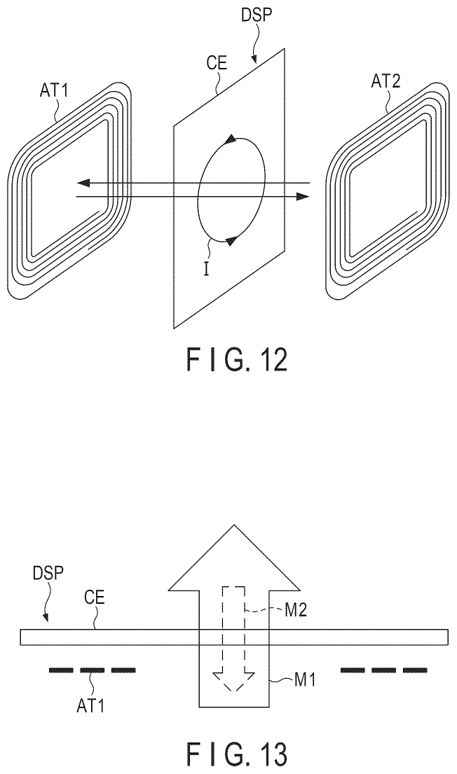

FIG. 12 and FIG. 13 are diagrams for explaining the effects of the display device DSP according to the embodiment. An electronic device on which the display device DSP is mounted may comprise an antenna AT1 for near field communication (NFC). The antenna AT1 is provided so as to, for example, face the rear side of the display device DSP (in other words, the lower surface of the substrate 10 shown in FIG. 3) and wirelessly communicates with the antenna AT2 of another electronic device through the display device DSP.

At the time of wireless communication between the antennas AT1 and AT2, eddy current I is generated in the common electrode CE by magnetic field M1 formed by the antenna AT1. By eddy current I, magnetic field M2 which negates magnetic field M1 is formed, and the signal strength is attenuated. Thus, when wireless communication is performed via the display device DSP, the communication sensitivity could be decreased. In particular, when the partition 6 mainly formed of a metal material and having a grating shape is formed in the entire display area DA, the resistance of the common electrode CE is low. Thus, a large eddy current I occurs, thereby generating a strong magnetic field M2. Thus, the communication sensitivity is easily decreased.

To the contrary, in the embodiment, the common electrode CE is divided into a plurality of segments SG by the slits SL. In this case, a large eddy current is not easily generated in the common electrode CE. Thus, the decrease in communication sensitivity can be prevented. Eddy current could be generated in each segment SG. However, the effect caused to communication sensitivity by this eddy current is tiny compared to eddy current I generated in the entire part of the common electrode CE which is not divided.

An electronic device on which the display device DSP is mounted may comprise an optical sensor such as an illumination sensor which detects external light. When such an optical sensor is provided on the rear side of the display device DSP, translucency is required in the display device DSP.

However, each of the lower electrodes LE1, LE2 and LE3 includes the reflective layer described above. In addition, the partition 6 which is at least partly formed of a metal material has light-shielding properties. For this reason, if the lower electrodes LE1, LE2 and LE3 and the partition 6 are formed in the entire display area DA, the light which is made incident on the display surface of the display device DSP could be mostly reflected or blocked without being transmitted to the rear side.

To the contrary, in the embodiment, the transmissive area TA shown in FIG. 6 and FIG. 9 is formed in the display area DA. Therefore, as explained with reference to FIG. 9, part of the external light which is made incident on the display surface is transmitted to the rear side of the display device DSP through the slit SL. By this configuration, the translucency of the display device DSP can be enhanced.

It should be noted that the partition 6 functions as lines for supplying electricity to the upper electrodes UE1, UE2 and UE3 and also functions to divide the stacked films FL1, FL2 and FL3 which are formed by vapor deposition when the display device DSP is manufactured. By dividing the stacked films FL1, FL2 and FL3 in this manner, the display elements DE1, DE2 and DE3 which are individually sealed by the sealing layers SE1, SE2 and SE3 can be obtained.

However, the partition 6 is divided in the slit SL. Thus, it is difficult to individually seal a plurality of subpixels SP1 which constitute the subpixel column CM shown in FIG. 5. If the both ends of the slit SL are completely open, the end portions of the stacked films FL1 of these subpixels SP1 could be exposed from the sealing layers SE1. In this case, if moisture enters a stacked film FL1 exposed from a sealing layer SE1, the subpixels SP1 which constitute the subpixel column CM may be degraded as a whole. Thus, a linear display failure may be caused.

However, in the embodiment, the first end portions E1 of the segments SG1 and SG2 are connected to each other by the connection portion CN (see FIG. 4) formed by the partition 6, and further, the second end portions E2 of the segments SG1 and SG2 are connected to each other by the high-resistive portion HR (see FIG. 11) formed by the partition 6. Thus, the subpixels SP1 which constitute the subpixel column CM are surrounded by the partition 6. This configuration allows the sealing layers SE1 to satisfactorily cover the end portions of the stacked films FL1 of these subpixels SP1. Thus, moisture incursion into the stacked films FL1 can be prevented.

Moreover, in the embodiment, each protrusion PT is provided between two subpixels SP1 of a plurality of subpixels SP1 which constitute the subpixel column CM. This configuration prevents a change in visual quality caused by the reflection of the partition 6 in the slit SL and the other portion of the display area DA. Thus, the display quality can be improved.

If the distal end portion Ea of each protrusion PT has an angular shape in plan view, the upper portion 62 may be broken, or the stacked film FL1 may not be sufficiently covered with the sealing layer SE1 in some portions. To the contrary, when the distal end portion Ea of each protrusion PT is rounded as shown in FIG. 6, the breaking of the upper portion 62 can be prevented, and further, the stacked film FL1 can be satisfactorily covered with the sealing layer SE1.

The configuration disclosed in the embodiment could be modified in various ways. The second to seventh embodiments described below disclose other examples of a configuration which could be applied to the partition 6 and the common electrode CE. The configurations and effects which are not particularly referred to in these embodiments are the same as those of the first embodiment.

### Second Embodiment

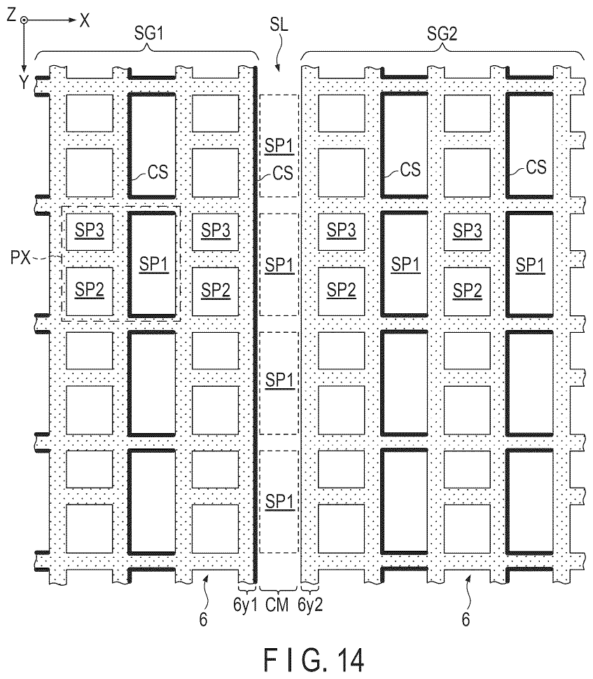

FIG. 14 is a schematic plan view in which segments SG1 and SG2 which are adjacent to each other via a slit SL are enlarged in a display device DSP according to a second embodiment.

In this embodiment, the first segment SG1 does not have any protrusion PT. From another view point, a partition 6 is not provided between subpixels SP1 which are adjacent to each other in a subpixel column CM. In this configuration, as a transmissive area TA (see FIG. 6) is expanded, the transmittance of the display device DSP can be further increased.

### Third Embodiment

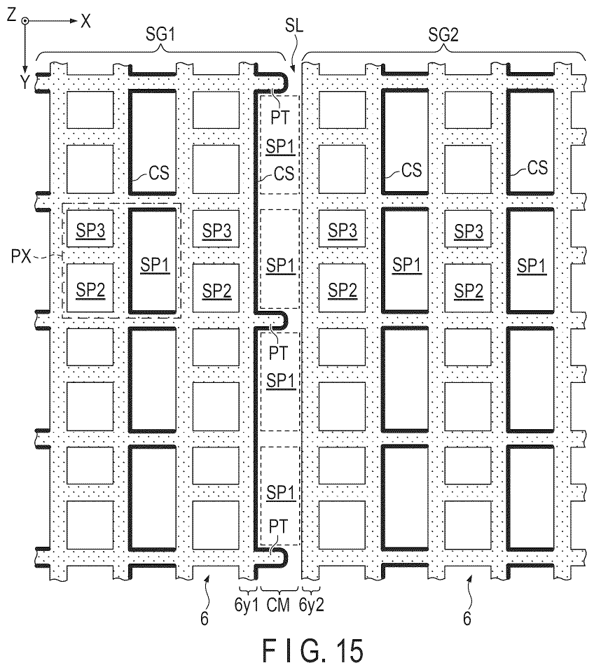

FIG. 15 is a schematic plan view in which segments SG1 and SG2 which are adjacent to each other via a slit SL are enlarged in a display device DSP according to a third embodiment. In this embodiment, the first segment SG1 has protrusions PT in a manner similar to that of the first embodiment. However, the number of protrusions PT is reduced compared to the example of FIG. 5.

In the example of FIG. 15, two subpixels SP1 are provided between two protrusions PT arranged in a Y-direction. However, the configuration is not limited to this example. Three or more subpixels SP1 may be provided between two protrusions PT.

This embodiment can increase the transmittance of the display device DSP in a manner similar to that of the second embodiment. If no protrusion PT is provided at all as in the case of the second embodiment, there is a possibility that the visual quality of a subpixel column CM along the slit SL differs from that of the other subpixel columns. In the configuration of this embodiment, an effect of improving the visual quality of the subpixel column CM can be expected.

### Fourth Embodiment

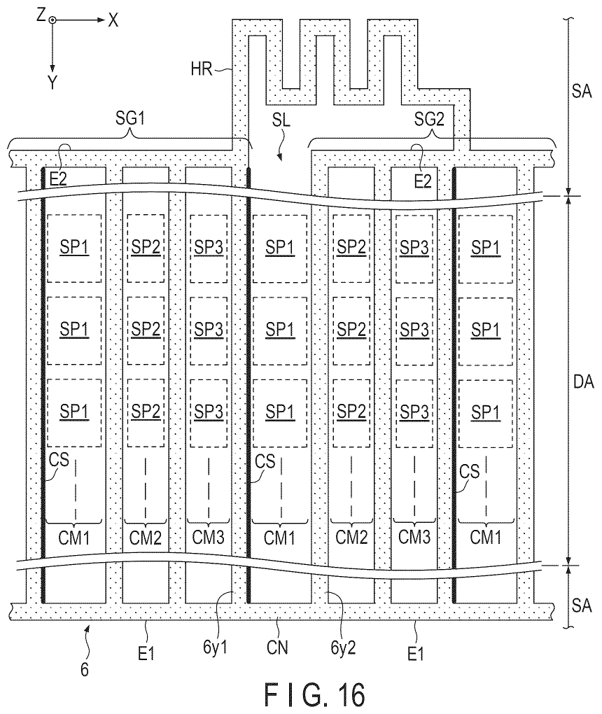

FIG. 16 is a schematic plan view in which segments SG1 and SG2 which are adjacent to each other via a slit SL are enlarged in a display device DSP according to a fourth embodiment.

In this embodiment, a display area DA has a subpixel column CM1 consisting of a plurality of subpixels SP1 arranged in a Y-direction, a subpixel column CM2 consisting of a plurality of subpixels SP2 arranged in the Y-direction and a subpixel column CM3 consisting of a plurality of subpixels SP3 arranged in the Y-direction. These subpixel columns CM1, CM2 and CM3 are alternately arranged in an X-direction.

For example, the widths of subpixels SP1, SP2 and SP3 in the Y-direction (in other words, the widths of pixel apertures AP1, AP2 and AP3 in the Y-direction) are equal to each other. To the contrary, in the example of FIG. 16, the width of each subpixel SP1 in the X-direction (in other words, the width of the pixel aperture AP1 in the X-direction) is greater than that of each of subpixels SP2 and SP3 in the X-direction (in other words, the width of each of the pixel apertures AP2 and AP3 in the X-direction). By this configuration, the aperture ratio of each subpixel SP1 is greater than that of each of subpixels SP2 and SP3. It should be noted that the configuration is not limited to this example. The widths of subpixels SP1, SP2 and SP3 in the X-direction may be equal to each other. Alternatively, the width of one of subpixels SP2 and SP3 in the X-direction may be greater than that of subpixel SP1 in the X-direction.

Each of the subpixel columns CM1, CM2 and CM3 is surrounded by a partition 6. The slit SL is provided along the subpixel column CM1. The first end portions E1 of the segments SG1 and SG2 are connected to each other by a connection portion CN which is part of the partition 6. The second end portions E2 of the segments SG1 and SG2 are connected to each other by a high-resistive portion HR which is similar to that of the first embodiment.

In the example of FIG. 16, the partition 6 is not provided between subpixels SP1 arranged in the Y-direction, between subpixels SP2 arranged in the Y-direction or between subpixels SP3 arranged in the Y-direction. In this configuration, in addition to the slit SL, the transmissive area TA described above is formed in other portions. Thus, the transmittance of the display device DSP can be further increased.

### Fifth Embodiment

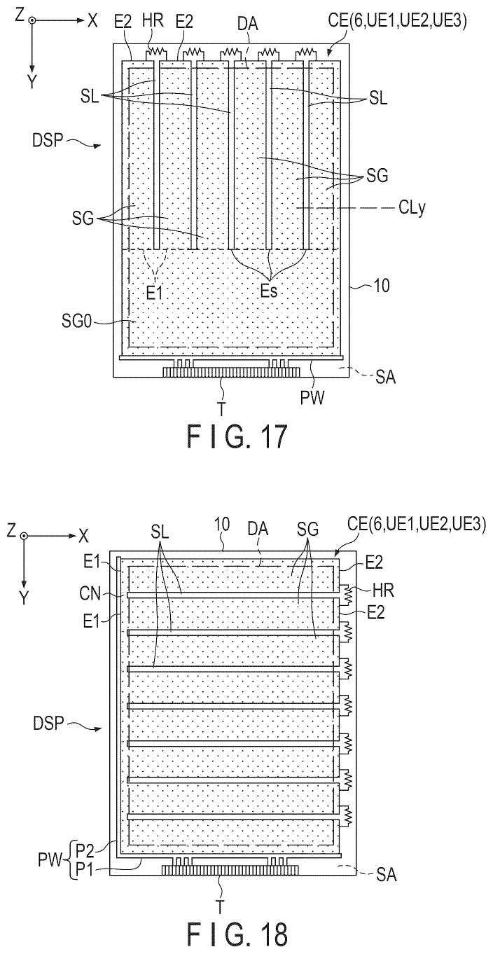

FIG. 17 is a schematic plan view showing some elements of a display device DSP according to a fifth embodiment. In the example of this figure, in a manner similar to that of the first embodiment, a plurality of slits SL extending in a Y-direction are provided in a common electrode CE, and by this configuration, the common electrode CE is divided into a plurality of segments SG arranged in an X-direction. A configuration which is similar to that of FIG. 5, FIG. 11, FIG. 14, FIG. 15 or FIG. 16 could be applied to the vicinity of each slit SL.

In the example of FIG. 17, the end portion Es of each slit SL on the power supply line PW side is located in a display area DA. By this configuration, a segment SG0 having a width greater than the width of each segment SG in the X-direction is formed between the segments SG and the power supply line PW.

An end of the segment SG0 in the Y-direction is connected to the first end portions E1 of the segments SG. The other end of the segment SG0 in the Y-direction is connected to the power supply line PW.

In the example of FIG. 17, the positions of the end portions Es of the slits SL in the Y-direction are aligned with each other. Further, these end portions Es are located on the power supply line PW side relative to the center CLy of the common electrode CE in the Y-direction. However, the configuration is not limited to this example. The positions of the end portions Es in the Y-direction may be misaligned with each other. The end portions Es may be located on the second end portion E2 side relative to the center CLy.

Even when the slits SL do not completely divide the common electrode CE in the display area DA as in the case of this embodiment, it is possible to obtain an effect of preventing the eddy current described above and an effect of improving the transmittance of the display device DSP.

### Sixth Embodiment

Each of the embodiments described above discloses a configuration in which each slit SL extends in a Y-direction. A sixth embodiment discloses a configuration in which each slit SL extends in an X-direction.

FIG. 18 is a schematic plan view showing some elements of a display device DSP according to the sixth embodiment. In the example of this figure, a plurality of slits SL extending in the X-direction are provided in a common electrode CE, and by this configuration, the common electrode CE is divided into a plurality of segments SG arranged in the Y-direction. From another viewpoint, in this embodiment, the slits SL extend parallel to the scanning lines G shown in FIG. 1.

The segments SG have a shape which is elongated in the X-direction and are arranged in the Y-direction. In the example of FIG. 18, the first end portions E1 of the adjacent segments SG are connected to each other by connection portions CN, and the second end portions E2 of the adjacent segments SG are connected to each other by high-resistive portions HR.

A power supply line PW has a first portion P1 extending in the X-direction and a second portion P2 extending in the Y-direction. The first portion P1 is located between a display area DA and a terminal portion T. The second portion P2 is provided along the left side of the display area DA in the figure. The first end portion E1 of each of the segments SG is connected to the second portion P2.

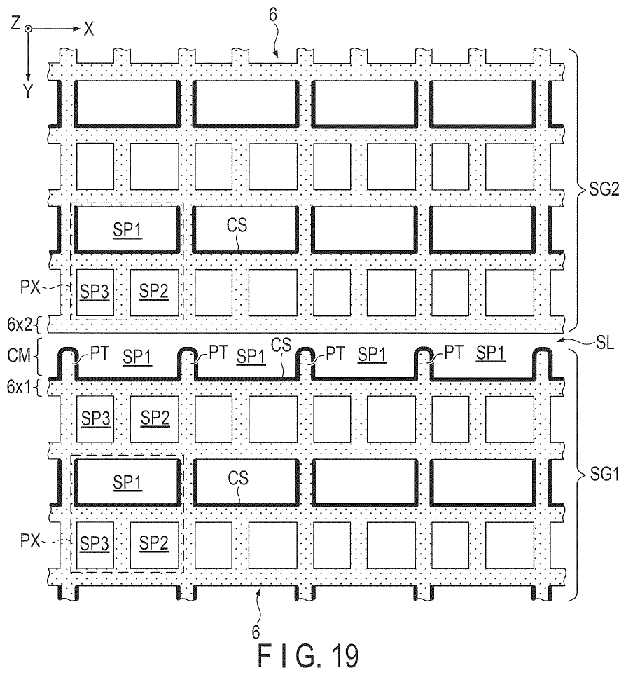

FIG. 19 is a schematic plan view in which two segments SG which are adjacent to each other via a slit SL are enlarged in the display device DSP according to the embodiment. In this embodiment, the segment SG located on the lower side of the slit SL in FIG. 19 is called a first segment SG1, and the segment SG located on the upper side is called a second segment SG2.

Each pixel PX includes subpixels SP1, SP2 and SP3 in a manner similar to that of the first embodiment. In the example of FIG. 19, subpixels SP2 and SP3 are arranged in the X-direction. Subpixels SP1 and SP2 are arranged in the Y-direction. Subpixels SP1 and SP3 are also arranged in the Y-direction. In a manner similar to that of the first embodiment, among subpixels SP1, SP2 and SP3, the aperture ratio of subpixel SP1 is the greatest, and the aperture ratio of subpixel SP3 is the least.

The first segment SG1 has a first partition 6x1 which is adjacent to the slit SL. The second segment SG2 has a second partition 6x2 which is adjacent to the slit SL. Both of these partitions 6x1 and 6x2 extend in the X-direction. A subpixel column CM located between the partitions 6x1 and 6x2 consists of a plurality of subpixels SP1 which are arranged in the X-direction.

The first segment SG1 has a plurality of protrusions PT. The protrusions PT extend from the first partition 6x1 toward the second partition 6x2 and are spaced apart from the second partition 6x2. In the example of FIG. 19, each protrusion PT is located between adjacent two subpixels SP1 of a plurality of subpixels SP1 which constitute the subpixel column CM. From another viewpoint, one subpixel SP1 is provided between two protrusions PT which are adjacent to each other in the X-direction.

Contact sides CS in which upper electrodes UE1 are in contact with the side surfaces of lower portions 61 are, for example, as shown by the thick lines in FIG. 19. Specifically, each upper electrode UE1 of the subpixel column CM is in contact with the lower portion 61 of the first partition 6x1 and is spaced apart from the lower portion 61 of the second partition 6x2.

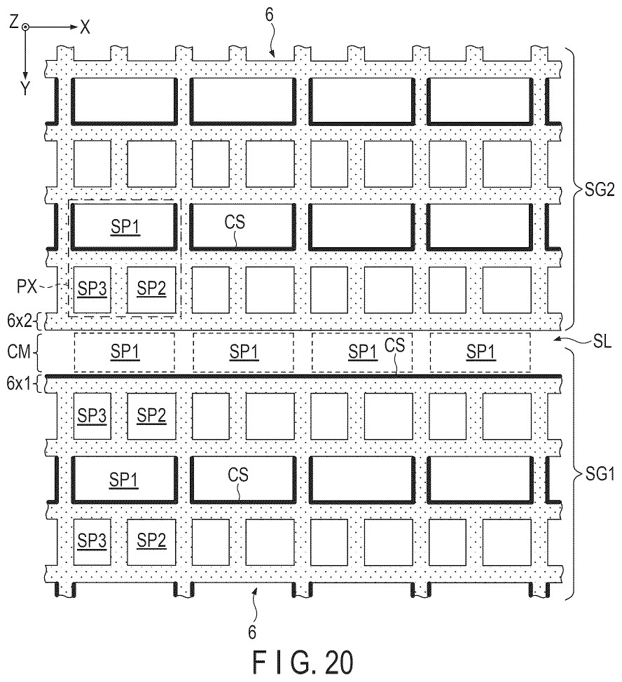

FIG. 20 is a schematic plan view showing another example which could be applied to the display device DSP according to the embodiment. In the example of this figure, the first segment SG1 does not have any protrusion PT. By this configuration, the transmittance of the display device DSP can be increased in a manner similar to that of the second embodiment.

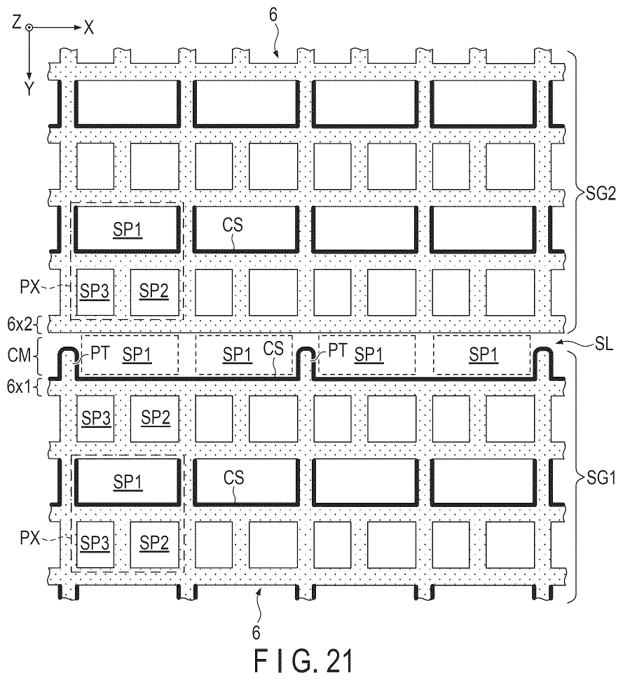

FIG. 21 is a schematic plan view showing yet another example which could be applied to the display device DSP according to the embodiment. In the example of this figure, although the first segment SG1 has protrusions PT, the number of protrusions PT is reduced compared to the example of FIG. 19. This configuration allows the attainment of both the improvement of the transmittance and the improvement of the visual quality of the subpixel column CM in a manner similar to that of the third embodiment.

In the example of FIG. 21, two subpixels SP1 are provided between two protrusions PT arranged in the X-direction. However, the configuration is not limited to this example. Three or more subpixels SP1 may be provided between two protrusions PT.

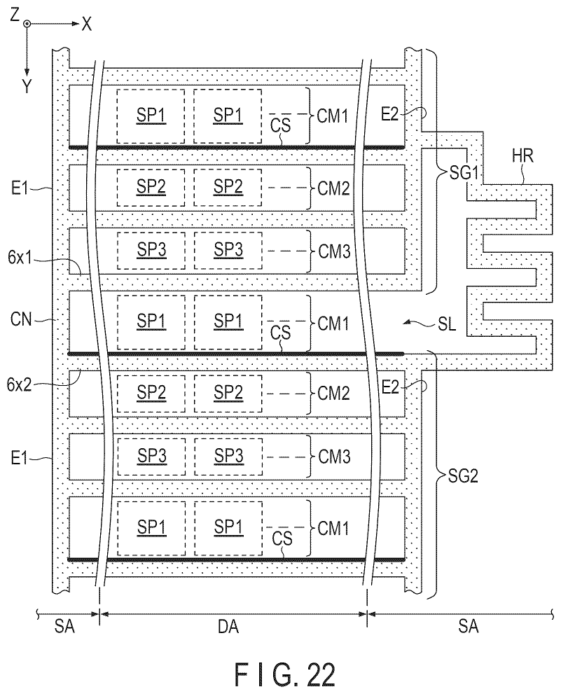

FIG. 22 is a schematic plan view showing yet another example which could be applied to the display device DSP according to the embodiment. In the example of this figure, in a manner similar to that of the fourth embodiment, a subpixel column CM1 consisting of a plurality of subpixels SP1, a subpixel column CM2 consisting of a plurality of subpixels SP2 and a subpixel column CM3 consisting of a plurality of subpixels SP3 are formed in the display area DA. However, these subpixel columns CM1, CM2 and CM3 extend in the X-direction.

For example, the widths of subpixels SP1, SP2 and SP3 in the X-direction (in other words, the widths of pixel apertures AP1, AP2 and AP3 in the X-direction) are equal to each other. To the contrary, in the example of FIG. 22, the width of each subpixel SP1 in the Y-direction (in other words, the width of the pixel aperture AP1 in the Y-direction) is greater than that of each of subpixels SP2 and SP3 in the Y-direction (in other words, the width of each of the pixel apertures AP2 and AP3 in the Y-direction). By this configuration, the aperture ratio of each subpixel SP1 is greater than that of each of subpixels SP2 and SP3. It should be noted that the configuration is not limited to this example. The widths of subpixels SP1, SP2 and SP3 in the Y-direction may be equal to each other. Alternatively, the width of one of subpixels SP2 and SP3 in the Y-direction may be greater than that of subpixel SP1 in the Y-direction.

Each of the subpixel columns CM1, CM2 and CM3 is surrounded by the partition 6. A slit SL is provided along the subpixel column CM1. The first end portions E1 of the segments SG1 and SG2 are connected to each other by a connection portion CN which is part of the partition 6. The second end portions E2 of the segments SG1 and SG2 are connected to each other by a high-resistive portion HR which is similar to that of the first embodiment.

In the example of FIG. 22, the partition 6 is not provided between subpixels SP1 arranged in the X-direction, between subpixels SP2 arranged in the X-direction or between subpixels SP3 arranged in the X-direction. By this configuration, the transmittance of the display device DSP can be further increased.

### Seventh Embodiment

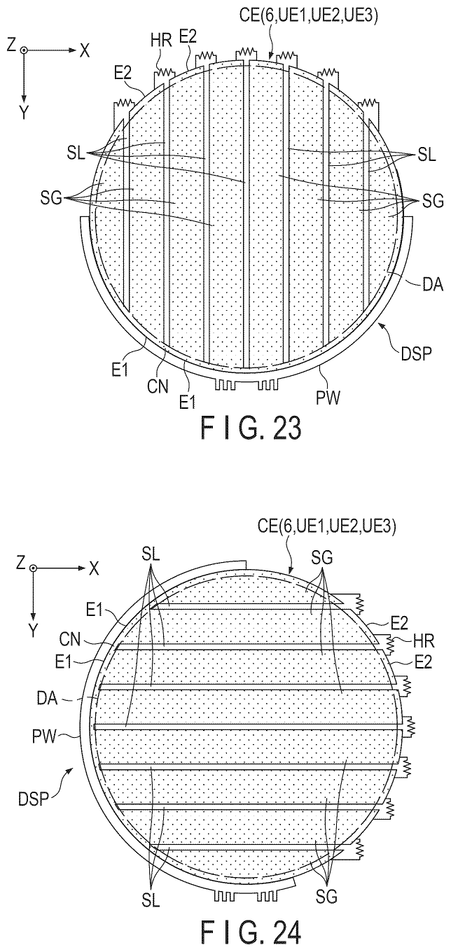

FIG. 23 is a schematic plan view showing some elements of a display device DSP according to a seventh embodiment. In this embodiment, a display area DA and a common electrode CE are circular.

In the example of FIG. 23, the common electrode CE is divided into a plurality of segments SG by a plurality of slits SL in a manner similar to that of each of the embodiments described above. Each slit SL extends parallel to a Y-direction. The first end portions E1 of the adjacent segments SG are connected to each other by connection portions CN. The second end portions E2 of the adjacent segments SG are connected to each other by high-resistive portions HR.

FIG. 24 is a schematic plan view showing another example of a configuration which could be applied to the display device DSP according to the embodiment. In the example of this figure, each slit SL extends parallel to an X-direction.

In both the example of FIG. 23 and the example of FIG. 24, a power supply line PW has a planar shape which is arcuate along the display area DA. The first end portion E1 of each segment SG is connected to the power supply line PW.

In the example of FIG. 23, a configuration which is similar to that of FIG. 5, FIG. 11, FIG. 14, FIG. 15 or FIG. 16 could be applied to the vicinity of each slit SL. In the example of FIG. 24, a configuration which is similar to that of FIG. 19, FIG. 20, FIG. 21 or FIG. 22 could be applied to the vicinity of each slit SL.

All of the display devices that can be implemented by a person of ordinary skill in the art through arbitrary design changes to the display device described above as the embodiments of the present invention come within the scope of the present invention as long as they are in keeping with the spirit of the present invention.

Various modification examples which may be conceived by a person of ordinary skill in the art in the scope of the idea of the present invention will also fall within the scope of the invention. For example, even if a person of ordinary skill in the art arbitrarily modifies the above embodiments by adding or deleting a structural element or changing the design of a structural element, or adding or omitting a step or changing the condition of a step, all of the modifications fall within the scope of the present invention as long as they are in keeping with the spirit of the invention.

Further, other effects which may be obtained from each embodiment and are self-explanatory from the descriptions of the specification or can be arbitrarily conceived by a person of ordinary skill in the art are considered as the effects of the present invention as a matter of course.

What is claimed is:

1. A display device comprising:
a plurality of subpixels arranged in a first direction and a second direction intersecting with the first direction; and
a partition which includes a conductive lower portion and an upper portion protruding from a side surface of the lower portion and surrounds the subpixels, wherein
the partition includes:
first and second partitions arranged across an intervening gap in the first direction and extending in the second direction; and
a plurality of protrusions extending from the first partition toward the second partition and spaced apart from the second partition.

2. The display device of claim 1, wherein
each of the protrusions has a distal end portion having a rounded planar shape.

3. The display device of claim 1, wherein
the subpixels include a plurality of first subpixels arranged in the second direction between the first partition and the second partition, and
each of the protrusions is provided between the first subpixels which are adjacent to each other in the second direction.

4. The display device of claim 3, wherein
each of the first subpixels is provided between the two protrusions which are adjacent to each other in the second direction.

5. The display device of claim 3, wherein
each of the subpixels includes:
a lower electrode;
an organic layer which covers the lower electrode and emits light based on application of voltage; and
an upper electrode which is in contact with the lower portion and covers the organic layer, and
the upper electrode of each of the first subpixels is in contact with the lower portion of the first partition and is not in contact with the lower portion of the second partition.

6. The display device of claim 5, wherein
the partition and the upper electrodes of the subpixels constitute a common electrode which overlaps a display area in which the subpixels are provided, and
the common electrode is divided into a first segment including the first partition and a second segment including the second partition by a slit.

7. The display device of claim 6, wherein
at least an end of the slit reaches an outer edge of the common electrode.

8. The display device of claim 7, wherein
the partition further comprises a high-resistive portion connecting the first segment and the second segment to each other in a surrounding area around the display area, and having a resistance which is higher than the first segment and the second segment.

9. The display device of claim 8, wherein
the high-resistive portion includes the lower portion and the upper portion and has a meandering shape in plan view.

10. The display device of claim 1, further comprising:
a plurality of pixel circuits provided in the subpixels, respectively;
a plurality of scanning lines which supply a scanning signal to the pixel circuits; and
a plurality of signal lines which supply a video signal to the pixel circuits, wherein
the first direction corresponds to an extension direction of the scanning lines, and
the second direction corresponds to an extension direction of the signal lines.

11. The display device of claim 1, further comprising:
a plurality of pixel circuits provided in the subpixels, respectively;
a plurality of scanning lines which supply a scanning signal to the pixel circuits; and
a plurality of signal lines which supply a video signal to the pixel circuits, wherein
the first direction corresponds to an extension direction of the signal lines, and
the second direction corresponds to an extension direction of the scanning lines.

12. A display device comprising:
a plurality of subpixels arranged in a first direction and a second direction intersecting with the first direction; and
a partition which includes a conductive lower portion and an upper portion protruding from a side surface of the lower portion and surrounds the subpixels, wherein
the partition includes first and second partitions arranged across an intervening gap in the first direction and extending in the second direction,
the subpixels include a plurality of first subpixels arranged in the second direction between the first partition and the second partition, and
the partition is not provided between the adjacent first subpixels.

13. The display device of claim 12, wherein
each of the subpixels includes:
a lower electrode;
an organic layer which covers the lower electrode and emits light based on application of voltage; and
an upper electrode which is in contact with the lower portion and covers the organic layer, and
the upper electrode of each of the first subpixels is in contact with the lower portion of the first partition and is not in contact with the lower portion of the second partition.

14. The display device of claim 13, wherein
the subpixels further include second and third subpixels which display colors different from each other and different from a color of the first subpixels, and
an aperture ratio of each of the first subpixels is greater than an aperture ratio of the second subpixel and an aperture ratio of the third subpixel.

15. The display device of claim 13, wherein
the partition and the upper electrodes of the subpixels constitute a common electrode which overlaps a display area in which the subpixels are provided, and
the common electrode is divided into a first segment including the first partition and a second segment including the second partition by a slit.

16. The display device of claim 15, wherein
at least an end of the slit reaches an outer edge of the common electrode.

17. The display device of claim 16, wherein
the partition further comprises a high-resistive portion connecting the first segment and the second segment to each other in a surrounding area around the display area and having a resistance which is higher than the first segment and the second segment.

18. The display device of claim 17, wherein
the high-resistive portion includes the lower portion and the upper portion and has a meandering shape in plan view.

19. The display device of claim 12, further comprising:
a plurality of pixel circuits provided in the subpixels, respectively;
a plurality of scanning lines which supply a scanning signal to the pixel circuits; and
a plurality of signal lines which supply a video signal to the pixel circuits, wherein
the first direction corresponds to an extension direction of the scanning lines, and
the second direction corresponds to an extension direction of the signal lines.

20. The display device of claim 12, further comprising:
a plurality of pixel circuits provided in the subpixels, respectively;
a plurality of scanning lines which supply a scanning signal to the pixel circuits; and
a plurality of signal lines which supply a video signal to the pixel circuits, wherein
the first direction corresponds to an extension direction of the signal lines, and
the second direction corresponds to an extension direction of the scanning lines.
